(19) United States
(12) Patent Application Publication
(10) Pub. No.: US 2018/0264687 A1
(43) Pub. Date: Sep. 20, 2018

(54) METAL MOLDS FOR POLYMER MICROWEDGE FABRICATION

(71) Applicants: David J. CARTER, Concord, MA (US); Tirunelveli S. SRIRAM, Acton, MA (US); Parshant KUMAR, Stoneham, MA (US); Clayton MORRIS, Norfolk, MA (US); William W. MCFARLAND, Waltham, MA (US); Eugene H. COOK, Acton, MA (US); John LE BLANC, North Andover, MA (US); Alla EPSHTEYN, Medford, MA (US); W. Dennis SLAFER, Arlington, MA (US); B. Diane MARTIN, Somerville, MA (US); THE CHARLES STARK DRAPER LABORATORY, INC., Cambridge, MA (US); MICROCONTINUUM, INC., Cambridge, MA (US)

(72) Inventors: David J. Carter, Concord, MA (US); Tirunelveli S. Sriram, Acton, MA (US); Parshant Kumar, Stoneham, MA (US); Clayton Morris, Norfolk, MA (US); William W. McFarland, Waltham, MA (US); Eugene H. Cook, Cambridge, MA (US); John LeBlanc, North Andover, MA (US); Alla Epshteyn, Medford, MA (US); W. Dennis Slafer, Arlington, MA (US); B. Diane Martin, Somerville, MA (US)

(21) Appl. No.: 15/534,918

(22) PCT Filed: Dec. 9, 2015
(86) PCT No.: PCT/US15/64798

§ 371 Date: Jun. 9, 2017

Related U.S. Application Data
(60) Provisional application No. 62/090,265, filed on Dec. 10, 2014.

(51) Int. Cl. B29C 33/30; B29C 33/38; B29C 33/42; B29C 33/68; B29C 39/02; C25D 1/10; C25D 5/34

(52) U.S. Cl. CPC B29C 33/307; B29C 33/3842; B29C 33/424; B81C 99/0085; B29C 39/026; C25D 1/10; C25D 5/34; B29C 33/68

(57) ABSTRACT

A method of forming a metal mold for casting a micro-scale dry adhesive structure includes securing a master patch of material including a micro-scale dry adhesive structure on a plating fixture, electroforming the metal mold on the patch of material, and removing the metal mold from the plating fixture and patch of material.

### CROSS-REFERENCE TO RELATED APPLICATION

This application claims priority under 35 U.S.C. §119(e) to U.S. Provisional Application Ser. No. 62/090,265 titled “DURABLE MICRO/NANO MOLD FABRICATION TECHNIQUES” filed Dec. 10, 2014, which is incorporated herein by reference in its entirety for all purposes.

### FIELD OF INVENTION

Aspects and embodiments disclosed herein are generally directed metal molds for casting to synthetic dry adhesive microstructures.

### BACKGROUND

The gecko is known for its ability to climb smooth vertical walls and even to suspend itself inverted from smooth surfaces. This ability is derived from the presence of elastic hairs called setae that split into nanoscale structures called spatulae on the feet and toes of geckos. The abundance and proximity to the surface of these spatulae make it sufficient for van der Waals forces alone to provide the required adhesive strength for a gecko to climb smooth vertical walls. Researchers have been inspired to create synthetic structures, sometimes referred to as “gecko adhesive,” that mimic the natural adhesive properties of gecko feet.

### SUMMARY

In accordance with one aspect, there is provided a method of forming a metal mold for casting a micro-scale dry adhesive structure. The method comprises securing a master patch of material including a micro-scale dry adhesive structure on a plating fixture, electroforming the metal mold on the master patch of material, and removing the metal mold from the master patch of material and the plating fixture.

In some embodiments, the method further comprises depositing an adhesion layer on the micro-scale dry adhesive structure, and depositing a release layer on the adhesion layer prior to electroforming the metal mold on the master patch of material.

In some embodiments, the master patch of material is mounted to a backing substrate and the method comprises securing the backing substrate in a cavity of the plating fixture.

In some embodiments, the method further comprises depositing fillets on an interface area between the backing substrate and the plating fixture.

In some embodiments, the micro-scale dry adhesive structure includes an array of microwedges having center lines disposed at an angle of between about 30 degrees and about 70 degrees relative to a plane defined by bases of the microwedges. The microwedges in the array of microwedges may have leading edges disposed at an angle of between about 20 degrees and about 65 degrees relative to the plane defined by the bases of the microwedges. The microwedges in the array of microwedges may have trailing edges disposed at an angle of between about 35 degrees and about 85 degrees relative to the plane defined by the bases of the microwedges. The microwedges in the array of microwedges may have heights of between about 80 μm and about 120 μm and bases of between about 20 μm and about 40 μm. The microwedges in the array of microwedges may have lengths of between about 120 μm and about 160 μm.

In some embodiments, the method further comprises depositing a layer of release agent on a portion of the metal mold.

In accordance with another aspect, there is provided a method of forming a mold for casting a micro-scale dry adhesive structure. The method comprises forming an array of stubs on a metal block and cutting a negative form of an array of micro-wedges from the array of stubs.

In some embodiments, the method comprises cutting between about 5 μm and about 10 μm or between about 10 μm and about 20 μm of metal from sides of the stubs in the array of stubs to form the negative form of the array of micro-wedges.

In some embodiments, the method comprises cutting the negative form of the array of micro-wedges from the stubs with a fine finishing tool. The method may comprise cutting the negative form of the array of micro-wedges from the stubs with a diamond micromachining tool. Forming the array of stubs may include cutting recesses in the metal block with a micromachining tool other than the diamond micromachining tool.

In some embodiments, forming the array of stubs includes 3D printing the stubs on the metal block.

In accordance with another aspect, there is provided a metal mold for casting a micro-scale dry adhesive structure. The metal mold comprises a metal block including an upper surface and a negative pattern for an array of micro-scale dry adhesive structures defined in the upper surface, the upper surface at least partially coated with a release agent to reduce adhesion between the metal mold and a casting material for the micro-scale dry adhesive structure.

In some embodiments, the array of micro-scale structures includes an array of microwedges.

In some embodiments, the microwedges have heights of between about 80 μm and about 120 μm and bases of between about 20 μm and about 40 μm. The microwedges may have center lines disposed at an angle of between of between about 30 degrees and about 70 degrees relative to a plane defined by bases of the microwedges. The microwedges may have leading edges disposed at an angle of between about 20 degrees and about 65 degrees relative to the plane defined by the bases of the microwedges. The microwedges may have trailing edges disposed at an angle of between about 35 degrees and about 85 degrees relative to the plane defined by the bases of the microwedges.

In accordance with another aspect, there is provided a method of casting a micro-scale dry adhesive structure in a metal mold. The method comprises providing a metal mold including a negative pattern for the micro-scale dry adhesive structure in an upper surface of the metal mold, depositing a casting material on the negative pattern, and curing the casting material.

In some embodiments, the method further comprises at least partially coating the upper surface with a release agent to reduce adhesion between metal mold and the casting material.

In some embodiments, the negative pattern includes a negative pattern for an array of microwedges having center lines disposed at an angle of between of between about 30 degrees and about 70 degrees relative to a plane defined by bases of the microwedges. The negative pattern may include a negative pattern for the array of microwedges with leading edges disposed at an angle of between about 20 degrees and about 65 degrees relative to the plane defined by the bases of the microwedges. The negative pattern may include a negative pattern for the array of microwedges with trailing edges disposed at an angle of between about 35 degrees and about 85 degrees relative to the plane defined by the bases of the microwedges.

In some embodiments, the method further comprises forming the metal mold with an electroplating process.

In some embodiments, the method further comprises machining the negative pattern into the upper surface of the metal mold.

In accordance with another aspect, there is provided a method of forming a mold for casting a micro-scale dry adhesive structure. The method comprises cutting a negative pattern of micro-wedges from the metal block with a diamond micromachining tool.

### BRIEF DESCRIPTION OF DRAWINGS

The accompanying drawings are not intended to be drawn to scale. In the drawings, each identical or nearly identical component that is illustrated in various figures is represented by a like numeral. For purposes of clarity, not every component may be labeled in every drawing. In the drawings:

FIG. 1A is an elevational view of a portion of an embodiment of a micro-scale dry adhesive structure including a pattern of microelements;

FIG. 1B is a close-up elevational view of an embodiment of microwedges that may be used in the micro-scale dry adhesive structure of FIG. 1A;

FIG. 2A is a close-up elevational view of an embodiment of microelements that may be used in the micro-scale dry adhesive structure of FIG. 1A;

FIG. 2B is a close-up elevational view of another embodiment of microelements that may be used in the micro-scale dry adhesive structure of FIG. 1A;

FIG. 3 illustrates a lip formed on an end of a micro-wedge of an embodiment of a micro-scale dry adhesive structure;

FIG. 4 illustrates an embodiment of a micro-scale dry adhesive structure disposed on a back plate and mounted on a plating fixture;

FIG. 5 illustrates the micro-scale dry adhesive structure of FIG. 4 coated with an adhesion layer and a release layer;

FIG. 6 illustrates the micro-scale dry adhesive structure of FIG. 5 coated with a conductive seed layer;

FIG. 7 illustrates a metal structure electrodeposited on the micro-scale dry adhesive structure of FIG. 6;

FIG. 8 illustrates the metal structure of FIG. 7 removed from the micro-scale dry adhesive structure and plating fixture to form a mold for casting micro-scale dry adhesive structures;

FIG. 9 illustrates an embodiment of a method of machining a mold for casting micro-scale dry adhesive structures; and

FIG. 10 illustrates a step of depositing a material for forming an embodiment of a micro-scale dry adhesive structure on a mold.

### DETAILED DESCRIPTION

Aspects and embodiments disclosed herein are not limited in application to the details of construction and the arrangement of components set forth in the following description or illustrated in the drawings. Aspects and embodiments disclosed herein are capable of being practiced or of being carried out in various ways. Also, the phraseology and terminology used herein is for the purpose of description and should not be regarded as limiting. The use of “including,” “comprising,” “having,” “containing,” “involving,” and variations thereof herein is meant to encompass the items listed thereafter and equivalents thereof as well as additional items.

### Micro-Scale Dry Adhesive Structures

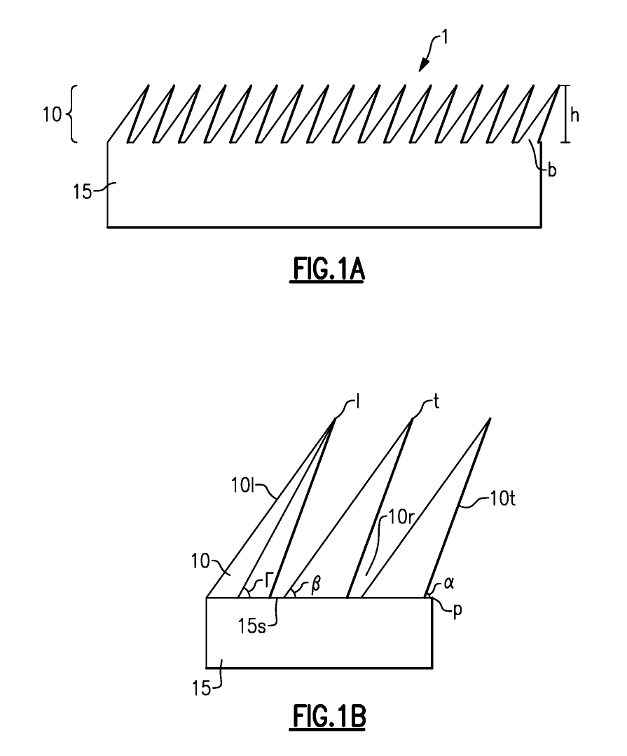

Aspects and embodiments disclosed herein are generally directed to the formation of novel synthetic “dry adhesive” structures (the term dry adhesive comprising both adhesive and/or friction enhancing structures) and methods and apparatus for making same. Dry adhesive and/or friction enhancing structures disclosed herein may include micro-scale elements, for example, elements having characteristic dimensions of less than about 100 μm, and are thus referred to herein as micro-scale dry adhesive structures. An example of an embodiment of a micro-scale dry adhesive structure including a pattern of micro-elements is illustrated in FIG. 1A. The micro-scale dry adhesive structure 1 includes a plurality of micro-elements, microwedges 10, disposed on a backing 15. The microwedges 10 may have heights h of about 80 μm and about 120 μm, bases b with widths of between about 20 μm and about 40 μm, and lengths of between about 120 μm and about 160 μm. As illustrated in FIG. 1A, the microwedges may include leading edges 101 angled at an angle Γ of between about 20 degrees and about 65 degrees from a line or plane p defined by an upper surface 15s of the backing 15b or the bases of the microwedges. The microwedges may include trailing edges 10t angled at an angle α of between about 35 degrees and about 85 degrees from line or plane p. The microwedges may include centerlines 1 that bisect the microwedges and that are angled at an angle β of between about 30 degrees and about 70 degrees from line or plane p. The microwedges 10 may have asymmetric tapers about their center lines 1. Tips t of the microwedges 10 may extend over the leading edges 101 of adjacent microwedges 10 and adjacent microwedges may define re-entrant spaces Γ defined below leading a trailing edge 10t of a first microwedge and above a leading edge 101 of a second microwedge 10 adjacent the first microwedge 10. These dimensions and angular ranges are examples, and aspects and embodiments disclosed herein are not limited to microwedge structures having these particular dimensions or angles.

Embodiments of the micro-scale dry adhesive structures disclosed herein may be formed from a polymer, for example, polydimethylsiloxane (PDMS), other silicones, polyurethane, or another polymeric material. Specific examples of polyurethanes that embodiments of the adhesive structures disclosed herein may be formed include M-3160 A/B polyurethane and L-3560 A/B polyurethane, available from BJB Enterprises. In some embodiments, the material from which embodiments of the micro-scale dry adhesive structures disclosed herein may be formed exhibit a Shore A hardness of between about 40 and about 60.

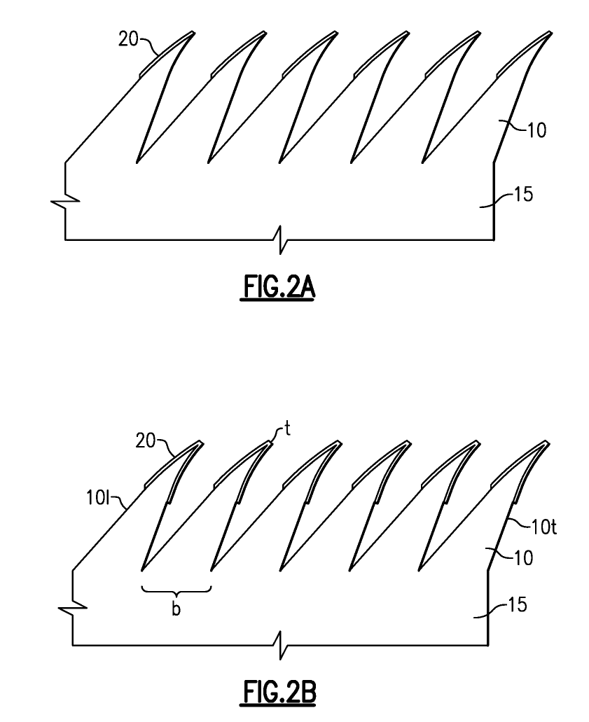

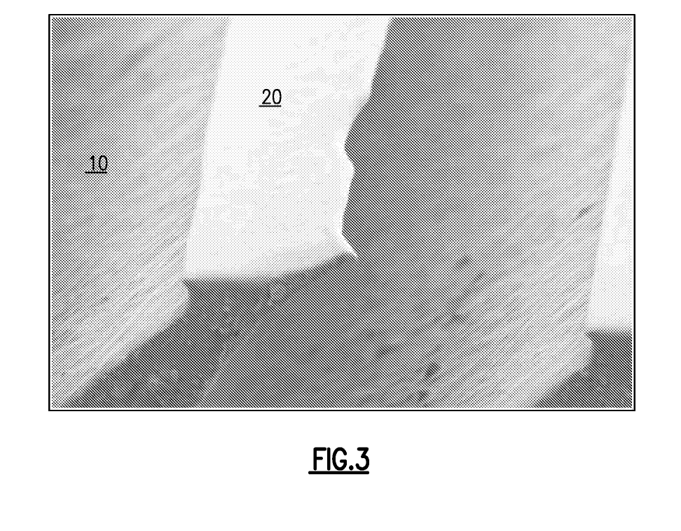

In some embodiments, the microwedges 10 of the micro-scale dry adhesive structure 1 may include an adhesion and/or friction enhancing layer, for example, lips 20 as illustrated in FIG. 2A, FIG. 2B and in the micrograph of FIG. 3. In some embodiments, the lips 20 have smoother surfaces than the microwedges 10 and may be added to the microwedges to increase the smoothness of portions of the microwedges proximate tips t of the microwedges 10. The lips 20 may be formed of an elastomeric material. The lips 20 may be formed from the same material as the remainder of the microwedges 10, but in some embodiments, may be formed of a different material that that of the remainder of the microwedges 10. The lips 20 may have smooth surfaces, as illustrated in FIG. 2A, FIG. 2B, and FIG. 3, but in other embodiments, may be patterned, for example, with ridges, columns, or other patterns. The in some embodiments, the lips 20 may be present on only portions of leading edges 101 of the microwedges 10, or in other embodiments may be present on both trailing edges 10t and leading edges 101 of the microwedges 10. (FIG. 2B.) Methods for forming the lips 20 are described in U.S. patent application Ser. No. 13/451,713, “SYNTHETIC DRY ADHESIVES,” which is incorporated herein by reference.

In some embodiments, the bases b of individual microwedges 10 may be spaced from one another, as illustrated in FIG. 1A, for example, by between about 0 μm and about 30 μm, and in other embodiments, for example, as illustrated in FIG. 2B, the trailing edge 10t of a first microwedge may intersect a leading edge 101 of a second microwedge 10 adjacent to the first microwedge 10 at bases b of the microwedges 10.

In some embodiments, the micro-scale dry adhesive structure may be mounted on a rigid base substrate, for example, a substrate including layers of carbon fibers and plywood, and/or of a rigid polymer (in some embodiments, glass-reinforced) to provide the micro-scale dry adhesive structure with enhanced mechanical stiffness and/or to maintain the microwedges 10 in a substantially same plane.

In some embodiments, micro-scale dry adhesive structures as illustrated in FIGS. 1-3 may be formed by a micromachining process, for example, by cutting material from a surface of a support or other substrate to form the microwedges. Due to the large number of microwedges that may be included in some embodiments of micro-scale dry adhesive structures (from thousands to millions), serial micromachining processes may be too slow to be practical for the production of large numbers of micro-scale dry adhesive structures. In other embodiments, micro-scale dry adhesive structures as illustrated in FIGS. 1-3 may be formed using microlithography and etching techniques as known in the semiconductor industry. Such microlithography and etching techniques, however, are often complex and costly and may have difficulty fabricating microwedge arrays with re-entrant profiles as desired in some implementations. Accordingly, processes that involve forming micro-scale dry adhesive structures by molding have been developed.

### Metal Molds for Micro-Scale Dry Adhesive Structures

In accordance with aspects disclosed herein, a mold for casting micro-scale dry adhesive structures that is more durable than a polymer or epoxy mold may be formed from a metal or metal alloy. In some embodiments, the metal mold may be formed by electroforming, micromachining, or a combination of the two.

A process for electroforming a metal mold for casting micro-scale dry adhesive structures is illustrated beginning at FIG. 4. As illustrated in FIG. 4, a known good micro-scale dry adhesive structure 1, for example, a micro-scale dry adhesive structure 1 formed in a wax mold as described in U.S. patent application Ser. No. 13/451,713, and optionally mounted on a backing substrate 225, is secured to and/or in a plating fixture 230. In some embodiments, a cavity 235 is formed in the plating fixture to receive the backing substrate 225.

In other embodiments, where the micro-scale dry adhesive structure 1 is not mounted on a backing substrate 225, the micro-scale dry adhesive structure 1 may be directly adhered to a flat upper surface 240 of the plating fixture 230 using any of a variety of adhesives known in the art, for example, double-stick tapes (e.g., REVALPHA™ thermal release tape, Nitto Denko Corporation) or glues (e.g., Sil-Poxy® silicone rubber adhesive, Smooth-On Inc.). A roller including a rigid tube covered with a compliant layer, for example, neoprene may be used to apply the micro-scale dry adhesive structure 1 to the plating fixture 230, squeezing the micro-scale dry adhesive structure 1 as it is applied to the plating fixture 230 to minimize the formation of air bubbles between the micro-scale dry adhesive structure 1 and the plating fixture 230.

The plating fixture 230 may comprise steel or any other rigid, and optionally, conductive, material. In some embodiments, the backing 15 of the micro-scale dry adhesive structure 1 may extend above the upper surface 240 of the plating fixture 230, for example, by about 0.027 inches (about 0.06 cm) to set a uniform 0.027 inch recess into the finished metal mold to form the backing 15 of additional micro-scale dry adhesive structures 1 from the finished metal mold.

A fillet 245, for example, an epoxy fillet, may be formed at the interface 250 between side walls of the backing 15 of the micro-scale dry adhesive structure 1 and the plating fixture 230. The epoxy fillet 245 is used to fill any gaps that might be present between the micro-scale dry adhesive structure 1 and the cavity 235 of the plating fixture 230 to prevent metal from being electroformed in any such gaps and forming undesired features on an electroformed mold or that may make it difficult to release the completed electroformed mold from the plating fixture 230.

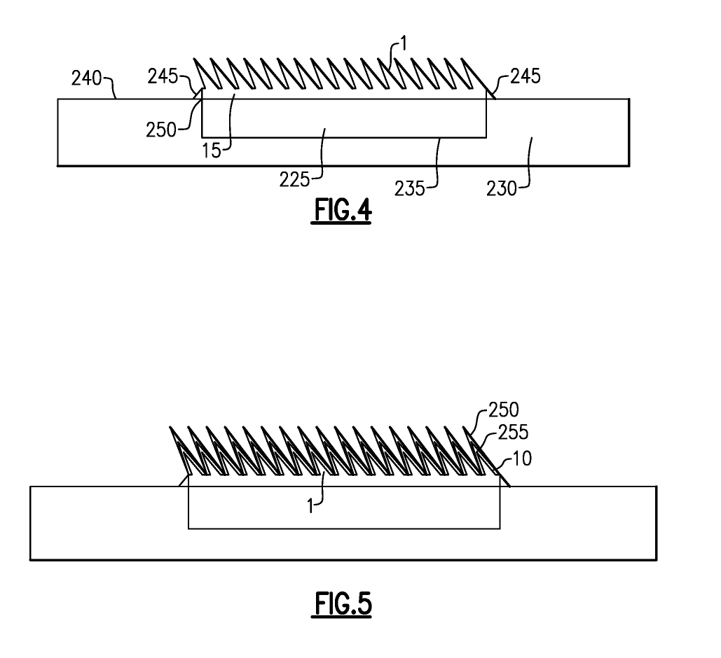

As illustrated in FIG. 5, the micro-elements 10 of the micro-scale dry adhesive structure 1 may be coated with a release layer 250 that will aid in releasing a metal mold electroformed on the micro-scale dry adhesive structure 1 from the micro-scale dry adhesive structure 1. In some embodiments, an adhesion layer 255 is first deposited on the micro-scale dry adhesive structure 1 to facilitate adhesion of the release layer 250 to the micro-scale dry adhesive structure 1. In some embodiments, the release layer 250 may include or consist of polytetrafluoroethylene (PTFE) or REPEL-SILANE™ and the adhesion layer 255 may include or consist of chromium and/or titanium. The adhesion layer 255 may be deposited on the micro-scale dry adhesive structure 1 by, for example, sputtering. The release layer 250 may be deposited on the adhesion layer 255 and/or micro-scale dry adhesive structure 1 by, for example, initiated chemical vapor deposition (iCVD) for PTFE, or vapor deposition for REPEL-SILANE™.

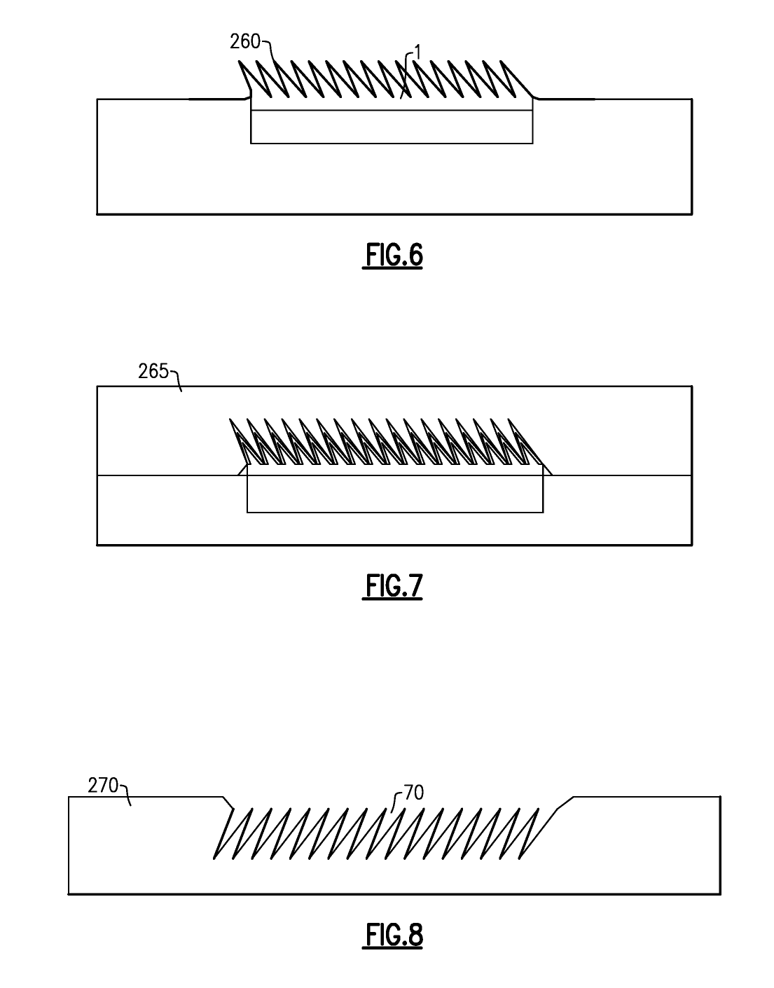

A seed metal layer 260, for example, a layer of molybdenum or copper, is deposited onto the release layer 250 or micro-scale dry adhesive structure 1 (FIG. 6, release layer 250 and adhesion layer 255 not shown for clarity) and the body 265 of the metal mold is formed on the seed layer 260, for example, by electroplating (FIG. 7, seed layer not visible). The body 265 of the metal mold may be the same metal as that of the seed layer 260 or a different metal, for example, copper, aluminum, steel, or a metal alloy.

The metal mold is then removed from the micro-scale dry adhesive structure 1 and plating fixture, resulting in a completed metal mold 270 (FIG. 8). The metal mold 270 may be inspected and in some embodiments, micromachining, for example, with a diamond tool or other micromachining tool to remove defects, to smooth surfaces of the metal mold 270, or to otherwise finish the metal mold 270. In some embodiments, a release agent, for example, PTFE, REPEL-SILANE™, or trichlorosilane may be coated on surfaces of the metal mold 270. The machined metal mold 270 may include negative microwedge patterns 70 having the same or similar dimensions and angles as the positive microwedges 10 discussed above with reference to FIG. 1B.

In other embodiments, the metal mold 270 may be used as an injection mold insert. The metal mold 270 may be placed in an injection molding apparatus in an opposed position to a backing substrate 225. A polymer material may be injected into the space between the metal mold 27 and the backing substrate 225 to form a micro-scale dry adhesive structure mounted on a backing substrate 225 in a single injection molding operation.

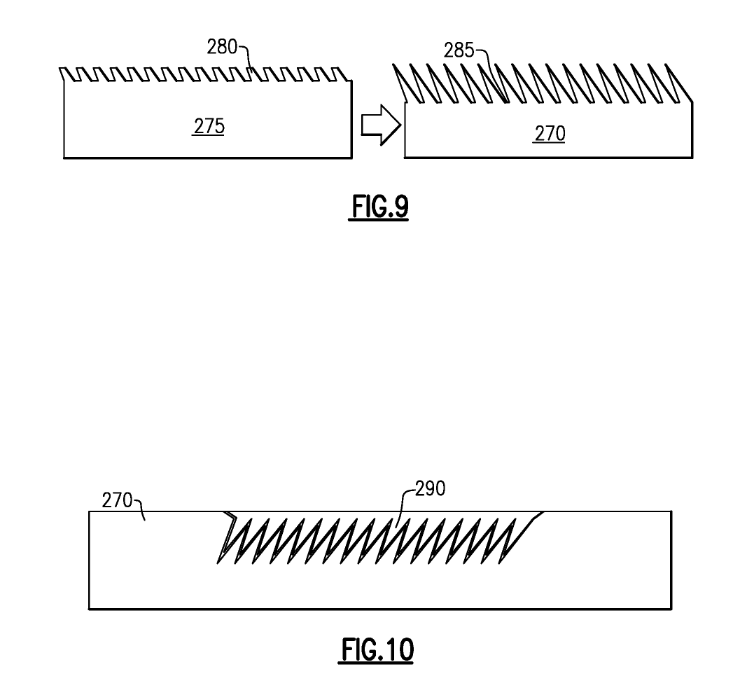

In other embodiments, a metal mold 270 for casting micro-scale dry adhesive structures may be formed without the use of a pre-fabricated micro-scale dry adhesive structure by directly machining a metal block 275. For example, a metal block 275 may optionally be roughly machined by standard micromachining tools, for example, micro-milling bits made from tool steel or polycrystalline diamond stock (˜0.001″-0.010″ in diameter), to form an array of wedge stubs 280 with a desired orientation, wedge angle and pitch. In some embodiments, cutouts between adjacent wedges may have dimensions, for example widths, about 10 μm to about 20 μm less than the cutouts that will be used to mold microwedges in a finished mold. A diamond tool or other fine finishing tool (formed from, for example silicon carbide or tool steel) may be used to further process the metal block 275 to form finished microgrooves 285 and complete the metal mold 270 (FIG. 9). Additionally or alternatively, a 3D printer may be utilized to form the array of wedge stubs 280 on the metal block 275. Electroplating may be performed on the 3D printed array of wedge stubs 280 to fill in voids left by the 3D printing operation and/or to smooth the array of wedge stubs 280. A diamond tool or other fine finishing tool may be used to further process the metal block 275 to form finished microgrooves 285 from the 3D printed array of wedge stubs 280 and complete the metal mold 270. Alternatively, the diamond or other fine finishing tool may be used to directly form wedge cutouts in a metal layer without first forming stubs (with the potential for more wear on the tool).

The metal mold 270 may be used for casting micro-scale dry adhesive structures. As illustrated in FIG. 10, a casting material 290, for example, PDMS, another silicone, or polyurethane, may be deposited in the pattern formed in the mold. The casting material may be left in the mold until it cures after which it may be removed to form a micro-scale dry adhesive structure, for example, as illustrated in FIG. 1A. Although not shown in this figure, the mold can incorporate a recess to ensure a uniform backing thickness for the cast structures.

Having thus described several aspects of at least one embodiment of this invention, it is to be appreciated various alterations, modifications, and improvements will readily occur to those skilled in the art. Such alterations, modifications, and improvements are intended to be part of this disclosure, and are intended to be within the spirit and scope of the invention. Accordingly, the foregoing description and drawings are by way of example only.

What is claimed is:

1. A method of forming a metal mold for casting a micro-scale dry adhesive structure, the method comprising:
securing a master patch of material including a micro-scale dry adhesive structure on a plating fixture;
electroforming the metal mold on the master patch of material; and
removing the metal mold from the master patch of material and the plating fixture.

2. The method of claim 1, further comprising depositing an adhesion layer on the micro-scale dry adhesive structure, and depositing a release layer on the adhesion layer prior to electroforming the metal mold on the master patch of material.

3. The method of claim 1, wherein the master patch of material is mounted to a backing substrate and the method comprises securing the backing substrate in a cavity of the plating fixture.

4. The method of claim 3, further comprising depositing fillets on an interface area between the backing substrate and the plating fixture.

5. The method of claim 1, wherein the micro-scale dry adhesive structure includes an array of microwedges having center lines disposed at an angle of between about 30 degrees and about 70 degrees relative to a plane defined by bases of the microwedges.

6. The method of claim 5, wherein microwedges in the array of microwedges have leading edges disposed at an angle of between about 20 degrees and about 65 degrees relative to the plane defined by the bases of the microwedges.

7. The method of claim 6, wherein the microwedges in the array of microwedges have trailing edges disposed at an angle of between about 35 degrees and about 85 degrees relative to the plane defined by the bases of the microwedges.

8. The method of claim 5, wherein the microwedges in the array of microwedges have heights of between about 80 μm and about 120 μm and bases of between about 20 μm and about 40 μm.

9. The method of claim 8, wherein the microwedges in the array of microwedges have lengths of between about 120 μm and about 160 μm.

10. The method of claim 1, further comprising depositing a layer of release agent on a portion of the metal mold.

11. A method of forming a mold for casting a micro-scale dry adhesive structure, the method comprising:
forming an array of stubs on a metal block; and
cutting a negative form of an array of micro-wedges from the array of stubs.

12. The method of claim 11, comprising cutting between about 5 μm and about 10 μm of metal from sides of the stubs in the array of stubs to form the negative form of the array of micro-wedges.

13. The method of claim 11, comprising cutting the negative form of the array of micro-wedges from the stubs with a fine finishing tool.

14. The method of claim 13, comprising cutting the negative form of the array of micro-wedges from the stubs with a diamond micromachining tool.

15. The method of claim 14, wherein forming the array of stubs includes cutting recesses in the metal block with a micromachining tool other than the diamond micromachining tool.

16. The method of claim 11, wherein forming the array of stubs includes 3D printing the stubs on the metal block.

17. A metal mold for casting a micro-scale dry adhesive structure, the metal mold comprising:
a metal block including an upper surface and a negative pattern for an array of micro-scale dry adhesive structures defined in the upper surface, the upper surface at least partially coated with a release agent to reduce adhesion between the metal mold and a casting material for the micro-scale dry adhesive structure.

18. The mold of claim 17, wherein the array of micro-scale structures includes an array of microwedges.

19. The mold of claim 17, wherein the microwedges have heights of between about 80 μm and about 120 μm and bases of between about 20 μm and about 40 μm.

20. The mold of claim 19, wherein the microwedges have center lines disposed at an angle of between of between about 30 degrees and about 70 degrees relative to a plane defined by bases of the microwedges.

21. The mold of claim 20, wherein the microwedges have leading edges disposed at an angle of between about 20 degrees and about 65 degrees relative to the plane defined by the bases of the microwedges.

22. The mold of claim 21, wherein the microwedges have trailing edges disposed at an angle of between about 35 degrees and about 85 degrees relative to the plane defined by the bases of the microwedges.

23. A method of casting a micro-scale dry adhesive structure in a metal mold, the method comprising:
providing a metal mold including a negative pattern for the micro-scale dry adhesive structure in an upper surface of the metal mold;
depositing a casting material on the negative pattern; and
curing the casting material.

24. The method of claim 23, further comprising at least partially coating the upper surface with a release agent to reduce adhesion between metal mold and the casting material.

25. The method of claim 23, wherein the negative pattern includes a negative pattern for an array of microwedges having center lines disposed at an angle of between of between about 30 degrees and about 70 degrees relative to a plane defined by bases of the microwedges.

26. The method of claim 25, wherein the negative pattern includes a negative pattern for the array of microwedges with leading edges disposed at an angle of between about 20 degrees and about 65 degrees relative to the plane defined by the bases of the microwedges.

27. The method of claim 26, wherein the negative pattern includes a negative pattern for the array of microwedges with trailing edges disposed at an angle of between about 35 degrees and about 85 degrees relative to the plane defined by the bases of the microwedges.

28. The method of claim 23, further comprising forming the metal mold with an electroplating process.

29. The method of claim 23, further comprising machining the negative pattern into the upper surface of the metal mold.

30. A method of forming a mold for casting a micro-scale dry adhesive structure, the method comprising cutting a negative pattern of micro-wedges from the metal block with a diamond micromachining tool.
